(19) United States
(12) Patent Application Publication
(10) Pub. No.: US 2024/0322043 A1
(43) Pub. Date: Sep. 26, 2024

(54) INTEGRATED CIRCUIT DEVICE

(71) Applicant: SAMSUNG ELECTRONICS CO., LTD., SUWON-SI (KR)

(72) Inventors: WOOYEOL MAENG, SUWON-SI (KR); CHANGKI BAEK, POHANG-SI (KR); KANGWOOK PARK, SUWON-SI (KR); HYANGWOO KIM, POHANG-SI (KR); KYOUNGHWAN OH, POHANG-SI (KR); HYUNGJIN LEE, SUWON-SI (KR)

(73) Assignee: Postech Research And Business Development Foundation, Gyeongsangbuk-do (KR)

(21) Appl. No.: 18/609,539

(22) Filed: Mar. 19, 2024

(30) Foreign Application Priority Data
Mar. 24, 2023 (KR) 10-2023-0039163
Apr. 26, 2023 (KR) 10-2023-0054972

(51) Int. Cl. H01L 29/78; H01L 29/40; H01L 29/49; H01L 29/66

(52) U.S. Cl. CPC H01L 29/7856; H01L 29/408; H01L 29/4983; H01L 29/66803; H01L 29/7835

(57) ABSTRACT

An integrated circuit device includes a fin body, a source and a drain disposed on the fin body, a channel disposed in the fin body between the source and the drain, a drain extension region disposed in the fin body between the drain and the channel, a gate insulating film disposed on the channel and the drain extension region, a high-permittivity layer disposed on the gate insulating film over the drain extension region, and a double gate including a first gate disposed on the gate insulating film above the channel adjacent to the source and a second gate in contact with the first gate. A first work function of the first gate is greater than a second work function of the second gate.

### CROSS-REFERENCE TO RELATED APPLICATION

This U.S. patent application claims priority under 35 U.S.C. § 119 to Korean Patent Application Nos. 10-2023-0039163, filed on Mar. 24, 2023, and 10-2023-0054972, filed on Apr. 26, 2023, in the Korean Intellectual Property Office, the disclosures of which are incorporated by reference in their entireties herein.

### 1. TECHNICAL FIELD

The inventive concept relates to an integrated circuit device, and more particularly, to an integrated circuit device including a high voltage transistor.

### 2. DISCUSSION OF RELATED ART

Recently, with the increase in demand for mobile devices such as mobile phones, laptop computers, and personal computers (PCs), demand for integrated circuit devices including high voltage transistors has been rapidly increasing. High voltage transistors may be required for input/output interface circuits, power management circuits, memory, and driving circuits for radio frequency (RF) amplifiers.

A fin field-effect transistor (FinFET) may be used as a high voltage transistor. The FinFET is a metal-oxide-semiconductor field-effect transistor (MOSFET) built on a substrate. However, an integrated circuit using the FinFET may have a low breakdown voltage or a high driving resistance.

### SUMMARY

At least one embodiment of the inventive concept provides an integrated circuit device including a high voltage transistor with improved electrical characteristics. For example, at least one embodiment of the inventive concept provides an integrated circuit including a drain extended FinFet with a high-permittivity field plate and a double gate. Accordingly, the integrated circuit may secure a high breakdown voltage and low driving resistance by increasing a short-channel immunity effect and conductivity, and at the same time, may implement an excellent high-frequency performance by securing high transconductance and output resistance.

According to an aspect of the inventive concept, there is provided an integrated circuit device including a fin body, a source, a drain, a channel, a drain extension region, a gate insulating film, a high-permittivity layer and a double gate. The source and the drain are disposed on the fin body. The channel is disposed in the fin body between the source and the drain. The drain extension region is disposed in the fin body between the drain and the channel. The gate insulating film is disposed on the channel and the drain extension region. The high-permittivity layer is disposed on the gate insulating film over the drain extension region. The double gate includes a first gate disposed on the gate insulating film above the channel adjacent to the source and a second gate in contact with the first gate. A first work function of the first gate is greater than a second work function of the second gate.

According to another aspect of the inventive concept, there is provided an integrated circuit device including a substrate, a fin body, a source, a drain, a channel, a drain extension region, a gate insulating film, a high-permittivity layer, and a double gate. The fin body protrudes above the substrate. The source and the drain are disposed on the fin body. The channel is disposed in the fin body between the source and the drain. The drain extension region is disposed in the fin body between the drain and the channel. The gate insulating film is disposed on the channel and the drain extension region. The high-permittivity layer is disposed on the gate insulating film over the drain extension region. The double gate includes a first gate disposed on the gate insulating film above the channel adjacent to the source and a second gate in contact with the first gate. The gate insulating film surrounds both upper and side surfaces of the channel and the drain extension region. The double gate surrounds both upper and side surfaces of the gate insulating film.

According to another aspect of the inventive concept, there is provided an integrated circuit device including a substrate, a fin body, a lower insulating layer, a source, a drain, a channel, a drain extension region, a gate insulating film, a high-permittivity layer, a first gate, and a second gate. The fin body protrudes in a vertical direction perpendicular to a surface of the substrate and extends in a horizontal direction parallel to the surface of the substrate. The lower insulating layer covers a lower side surface of the fin body. The source and the drain are spaced apart from each other in the horizontal direction on respective sides of the fin body. The channel is disposed in the fin body between the source and the drain in the horizontal direction. The drain extension region is disposed in the fin body between the drain and the channel in the horizontal direction. The gate insulating film is disposed on the channel and the drain extension region. The high-permittivity layer is disposed on the gate insulating film above the drain extension region. The first gate is disposed on the gate insulating film above the channel and adjacent to the source, and has a first work function. The second gate is disposed on the gate insulating layer in contact with the first gate and has a second work function that is less than the first work function.

### BRIEF DESCRIPTION OF THE DRAWINGS

Embodiments will be more clearly understood from the following detailed description taken in conjunction with the accompanying drawings in which:

FIG. 1 is a schematic perspective view illustrating an integrated circuit device including a drain extended FinFET according to an embodiment;

FIG. 2 is a plan view of the integrated circuit device of FIG. 1;

FIGS. 3A and 3B are cross-sectional views taken along lines A-A′ and B-B′ of FIG. 2, respectively;

FIG. 4 is a cross-sectional view illustrating an integrated circuit device including a drain extended FinFET according to an embodiment;

FIG. 5 is a cross-sectional view illustrating an integrated circuit device including a drain extended FinFET according to an embodiment;

FIGS. 6A to 13B are cross-sectional views illustrating a method of manufacturing an integrated circuit device including a drain extended FinFET according to an embodiment;

FIG. 14 is a diagram illustrating an electric field distribution of an integrated circuit device having a high-permittivity field plate and a double gate according to an embodiment;

FIGS. 15A and 15B are diagrams illustrating a conduction band of an integrated circuit device having a high-permittivity field plate and a double gate according to an embodiment;

FIG. 16 is a diagram illustrating an electron velocity and an integral value of electron velocity of an integrated circuit device having a high-permittivity field plate and a double gate according to an embodiment;

FIG. 17 is a diagram illustrating drain current and transconductance according to a gate voltage of an integrated circuit device having a high-permittivity field plate and a double gate according to an embodiment;

FIG. 18 is a diagram illustrating drain current and output resistance according to a drain voltage of an integrated circuit device having a high-permittivity field plate and a double gate according to an embodiment;

FIGS. 19A and 19B are diagrams illustrating a DIBL value, a breakdown voltage, a driving resistance, and a figure of merit of an integrated circuit device having a high-permittivity field plate and a double gate according to an embodiment; and

FIGS. 20A and 20B are diagrams illustrating a cut-off frequency and maximum oscillation frequency according to drain current of an integrated circuit device having a high-permittivity field plate and a double gate according to an embodiment.

### DETAILED DESCRIPTION OF THE EMBODIMENTS

Hereafter, the inventive concept will be described more fully with reference to the accompanying drawings The following embodiments according to the inventive concept may be implemented with only one embodiment, and also, may be implemented in combination with one or more embodiments. Therefore, the technical spirit of the inventive concept should not be construed as being limited to one embodiment. In the specification, the singular forms include the plural forms unless the context clearly indicates otherwise.

In the present specification, a high voltage transistor included in an integrated circuit device of the technical concept of the inventive concept may be a drain extended field effect transistor (FinFET). The drain extended FinFET may be a drain extended field effect transistor using a fin.

In addition, while the conductivity type or doped region of components may be described herein as p-type or n-type according to the characteristics of the main carrier, this is merely for convenience of explanation and the technical idea of the inventive concept is not limited thereto. For example, the term “p-type” or “n-type” may be used as a more general term, first conductivity type, or a second conductivity type opposite to the first conductivity type, where the first conductivity type may be p-type or n-type, and second conductivity type may be n-type or p-type. In the following description, an n-channel drain extended FinFET will be described as an

example to describe an integrated circuit device according to the technical concept of the inventive concept. However, this is for convenience of description, and the technical idea of the inventive concept is not limited thereto. An integrated circuit device including a combination of an n-channel drain extended FinFET and a p-channel drain extended FinFET may be provided by applying various modifications and changes within the scope of the technical idea of the inventive concept. In the following description, permittivity may mean relative permittivity, that is, a dielectric constant.

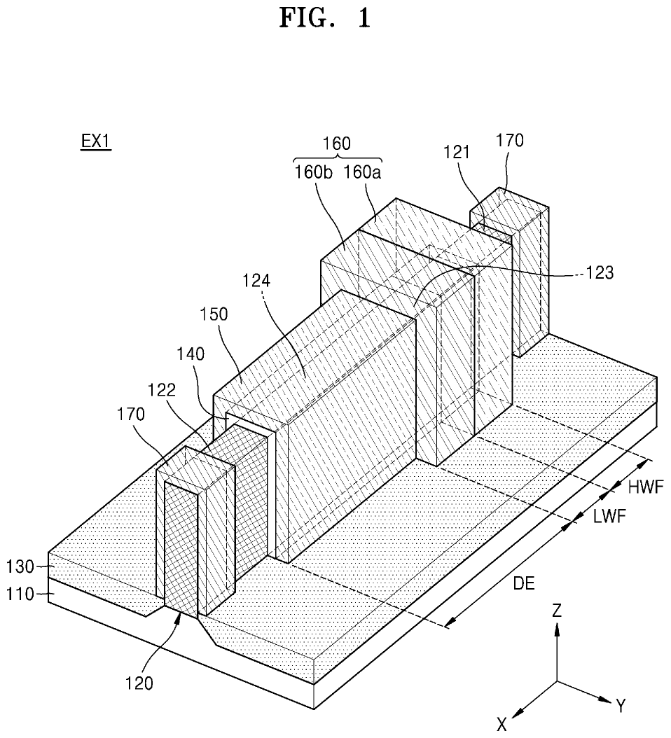

FIG. 1 is a schematic perspective view illustrating an integrated circuit device EX1 including a drain extended FinFET according to an embodiment.

In an embodiment, the integrated circuit device EX1 includes a drain extended FinFET having a high-permittivity field plate 150 and a double gate 160. The integrated circuit element

EX1 may further include a substrate 110, a fin body 120, a lower insulating layer 130, a source 121 (e.g., a source electrode), a drain 122 (e.g., a drain electrode), and a channel 123 formed in the fin body 120, a drain extension region 124, a gate insulating film 140.

The fin body 120 may be formed on the substrate 110. The fin body 120 may be formed to protrude from the substrate 110 in a third direction (Z direction) and extend in a first direction

(X direction) perpendicular to the third direction (Z direction). Because the third direction (Z direction) is a direction perpendicular to a surface of the substrate 110, the third direction may be referred to as the vertical direction.

Because the first direction (X direction) is a direction parallel to the surface of the substrate 110, the first direction may be referred to as a first horizontal direction. Because the second direction (Y direction) is perpendicular to the first direction (X direction) and parallel to the surface of the substrate 110, it may be referred to as a second horizontal direction.

The fin body 120 may be formed by patterning and etching the substrate 110 using a photolithography process. In an embodiments, the fin body 120 includes the same material as the substrate 110. The lower insulating layer 130 may be formed on both sides of the fin body 120 to prevent an electrical connection between the fin body 120 and other elements.

The lower insulating layer 130 may be formed on the substrate 110 on both sides of the fin body 120. In an embodiment, an upper surface of the fin body 120 is higher than an upper surface of the lower insulating layer 130. The fin body 120 may have a shape protruding from the lower insulating layer 130.

The source 121, the drain 122, the channel 123, and the drain extension region 124 may be formed in the fin body 120 in the first direction (X direction). The source 121 and the drain 122 may be formed on one side and the other side of the fin body 120, respectively.

In an embodiment, after forming a mask on the fin body 120, a high-concentration n-type dopant is implanted in the fin body 120, and the source 121 and the drain 122 are formed by using the formed mask.

In an embodiment, after forming a mask on portions of the fin body 120 and etching the portions of the fin body 120 where the source 121 and drain 122 are formed using the formed mask, regions of the source 121 and drain 122 including an n-type dopant may be formed by using a selective epitaxial growth method.

The channel 123 and the drain extension region 124 may be formed in a region of the fin body 120 between the source 121 and the drain 122. In an embodiment, the channel 123 is formed adjacent to the source 121 and the drain extension region 124 is formed between the channel 123 and the drain 122.

The channel 123 and the drain extension region 124 may be formed between the source 121 and the drain 122. In an embodiment, the drain extension region 124 is formed by implanting an n-type dopant having a lower dopant concentration than the source 121 and the drain 122 into the fin body 120.

The gate insulating film 140 may be formed on the channel 123 and the drain extension region 124. In an embodiment, the gate insulating film 140 is formed to surround both upper and side surfaces of the channel 123 and the drain extension region 124.

In an embodiment, the high-permittivity field plate 150 is formed on the gate insulating film 140 over the drain extension region 124. The high-permittivity field plate 150 may include an insulating layer having a high dielectric constant. For example, the high-permittivity field plate 150 may include a material having a high permittivity such as hafnium oxide (HfO₂).

In an embodiment, the high-permittivity field plate 150 is formed to surround both upper and side surfaces of the gate insulating film 140 surrounding the drain extension region 124. The high-permittivity field plate 150 may entirely surround the drain extension region 124. The double gate 160 may be formed on the gate insulating film 140 over the channel 123.

The double gate 160 may be formed on the gate insulating film 140 except for the drain extension region 124. In an embodiment, the double gate 160 does not overlap the drain extension region 124. In an embodiment, the double gate 160 includes a first gate 160a having a first work function and a second gate 160b having a second work function smaller than the first work function. The first gate 160a and the second gate 160b may be formed to contact each other. The first gate 160a may be formed adjacent to the source 121. A contact electrode 170 may be formed on the source 121 and the drain 122. For example, a first contact electrode may be formed on the source 121 and a second contact electrode may be formed on the drain 122.

The integrated circuit device EX1 may include a high work function gate region HWF, a low work function gate region LWF, and a drain extension region DE between the source 121 and the drain 122. In the integrated circuit device EX1, the high work function gate region HWF, the low work function gate region LWF, and the drain extension region DE may be positioned a certain distance away from the source 121 in the first direction (X direction).

In the integrated circuit device EX1 according to an embodiment of the inventive concept, by forming the high-permittivity field plate 150 on the drain extension region 124, an electric field peak formed between the channel 123 and the drain 122 may be effectively dispersed, as described below in detail. Accordingly, the integrated circuit element EX1 according to an embodiment of the inventive concept may obtain a high breakdown voltage and low driving resistance by increasing the short-channel immunity effect and conductivity.

In addition, in the integrated circuit device EX1 according to an embodiment of the inventive concept, the double gate 160 is formed on the gate insulating film 140 above the channel 123 to form a step-type electric field in the channel 123, as described in detail below. Accordingly, an effect of accelerating electrons and blocking a high voltage to the drain 122 may be obtained. Accordingly, the integrated circuit element EX1 according to an embodiment of the inventive concept may increase the short-channel immunity effect and the conductivity, thereby increasing transconductance and output resistance.

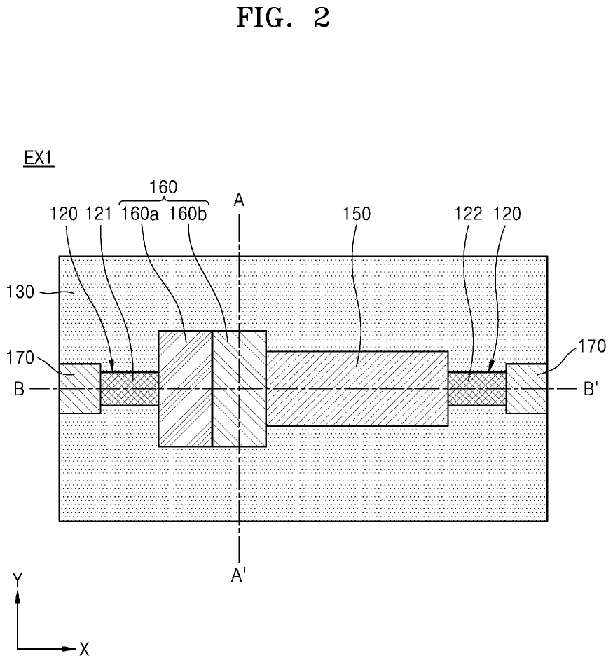

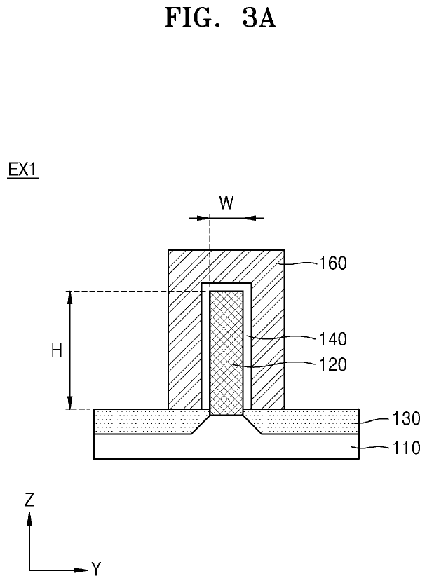

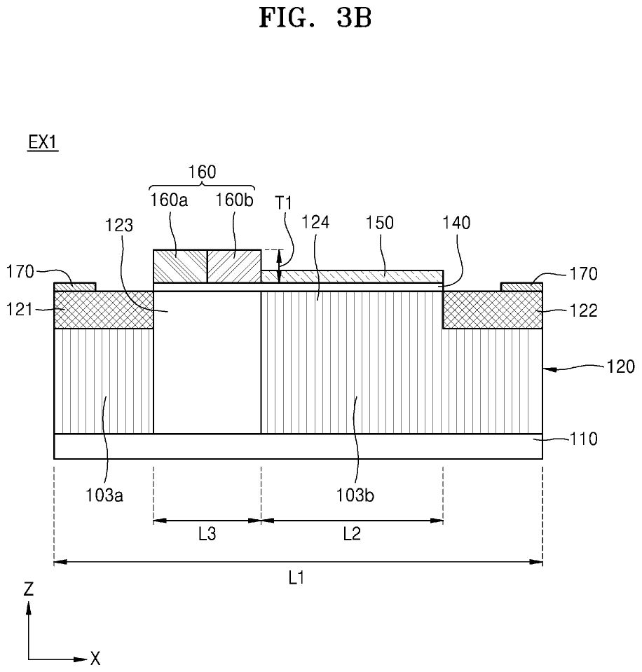

FIG. 2 is a plan view of the integrated circuit device of FIG. 1, and FIGS. 3A and 3B are cross-sectional views taken along lines A-A′ and B-B′ of FIG. 2, respectively.

In an embodiment, the integrated circuit element EX1 includes the fin body 120, the lower insulating layer 130, the source 121, the drain 122, the channel 123, the drain extension region 124, the gate insulating film 140, the high-permittivity field plate 150, and the double gate 160.

As shown in FIGS. 2 and 3B, the fin body 120 may be disposed extending in the first direction (X direction). The fin body 120 may be formed on the substrate 110. In some embodiments, the substrate 110 may be a semiconductor substrate such as silicon (Si) or silicon on insulator (SOI). The substrate 110 may have a first conductivity type. For example, the substrate be a p-type semiconductor substrate. As shown in FIG. 3A, the fin body 120 may be formed to protrude from the substrate 110 in the third direction (Z direction).

In some embodiments, the fin body 120 may have a width W in a range of several nanometer (nm) to several micrometer (μm), as shown in FIG. 3A, and may have a height H in a range from about tens of nm to about hundreds of nm. In some embodiments, a length L1 of the fin body 120 may be in a range of several tens of nm to several μm, as shown in FIG. 3B.

The lower insulating layer 130 may be formed on both sides of the fin body 120 on the substrate 110, as shown in FIGS. 2 and 3A. In some embodiments, the lower insulating layer 130 may include silicon oxide (SiO₂) or silicon nitride (Si₃N₄).

In the fin body 120, the source 121, the channel 123, the drain extension region 124, and the drain 122 may be sequentially disposed in the first direction (X direction). As shown in FIGS. 2 and 3B, the source 121 and the drain 122 may be formed on one side and the other side of the fin body 120 in the first direction (X direction), respectively.

The source 121 and the drain 122 may be formed by implanting a high-concentration second conductivity type dopant, for example, an n-type dopant into the fin body 120. The source 121 and the drain 122 may be a high-concentration second conductivity type region, for example, an n-type region. The source 121 may be formed to have a second conductivity type, for example, a p-type well 103a. The drain 122 may be formed to have the second conductivity type, for example, an n-type well 103b. The second conductivity type may be opposite to the first conductivity type.

The channel 123 and the drain extension region 124 may be formed in a region between the source 121 and the drain 122 within the fin body 120 in the first direction (X direction). In an embodiment, the channel 123 has the same first conductivity type as the substrate 110, for example, p-type.

In an embodiment, the channel 123 is disposed in a region having the first conductivity type. For example, the channel 123 may formed in a region outside the p-type well 103a and outside the n-type well 103b. The channel 123 may include a semiconductor layer of the first conductivity type having the same conductivity as that of the substrate 110. The channel 123 may have a channel length L3. As shown in FIG. 3B, the channel length L3 may be in a range of several nm to several μm.

In an embodiment, the drain extension region 124 is formed to have the second conductivity type, for example, the n-type well 103b. In some embodiments, a length L2 of the drain extension region 124 may be in a range from several nm to several μm, as shown in FIG. 3B. The gate insulating film 140 may be formed on the channel 123 and the drain extension

region 124, as shown in FIG. 3B. As shown in FIG. 3A, the gate insulating film 140 may be formed to surround both upper and side surfaces of the channel 123 and the drain extension region 124.

In some embodiments, the gate insulating film 140 may be formed by including at least one of silicon dioxide (SiO₂), hafnium oxide (HfO₂), silicon nitride (Si₃N₄), aluminum oxide (Al₂O₃), titanium dioxide (TiO₂), zirconium oxide (ZrO₂), tantalum oxide (Ta₂O₅), and lanthanum oxide (La₂O₃).

The high-permittivity field plate 150 may be formed on the gate insulating film 140 above the drain extension region 124, as shown in FIG. 3B. In an embodiment, the high-permittivity field plate 150 is formed to surround both upper and side surfaces of the gate insulating film 140 surrounding the drain extension region 124. The high-permittivity field plate 150 may have a form surrounding all of the drain extension region 124.

In some embodiments, the high-permittivity field plate 150 may be formed by including at least one of silicon dioxide (SiO₂), hafnium oxide (HfO₂), silicon nitride (Si₃N₄), aluminum oxide (Al₂O₃), titanium dioxide (TiO₂), zirconium oxide (ZrO₂), tantalum oxide (Ta₂O₅), and lanthanum oxide (La₂O₃).

In an embodiment, the high-permittivity field plate 150 includes a material having a higher permittivity than silicon dioxide (SiO₂). In an embodiment, the high-permittivity field plate 150 includes or is a material having a high permittivity of 3.9 or more. In an embodiments, the high-permittivity field plate 150 includes or is a material having a high dielectric constant in a range from about 3.9 to about 1600.

The double gate 160 may be formed on a portion of the gate insulating film 140. The double gate 160 may be formed on the gate insulating film 140 except for the drain extension region 124. In an embodiment, the double gate 160 does not overlap the drain extension region 124. The double gate 160 may include the first gate 160a having a first work function and the second gate 160b having a second work function that is less than the first work function.

In an embodiment, the first gate 160a and the second gate 160b include different materials. In some embodiments, the first gate 160a and the second gate 160b may include the same material having different impurity doping concentrations, such as polysilicon. In some embodiments, the first gate 160a and the second gate 160b may include at least one of impurity-doped polysilicon, metal, or metal nitride.

In some embodiments, the first gate 160a and the second gate 160b may include at least one of titanium (Ti), tantalum (Ta), tungsten (W), molybdenum (M), titanium nitride (TiN), tantalum nitride (TaN), tungsten nitride (WN), molybdenum nitride (MoN), copper (Cu), gold (Au), and cobalt (Co).

In an embodiment, the first gate 160a and the second gate 160b have the same thicknesses T1. In addition, in FIG. 3B, although the first gate 160a and the second gate 160b are illustrated as being formed as a single layer, the first gate 160a and the second gate 160b may be formed as a multiple layer in which a plurality of materials described above are stacked. The contact electrode 170 may be formed on the source 121 and the drain 122. For example, a first contact electrode 170 may be formed on the source 121 and a second contact electrode 170 may be formed on drain 122.

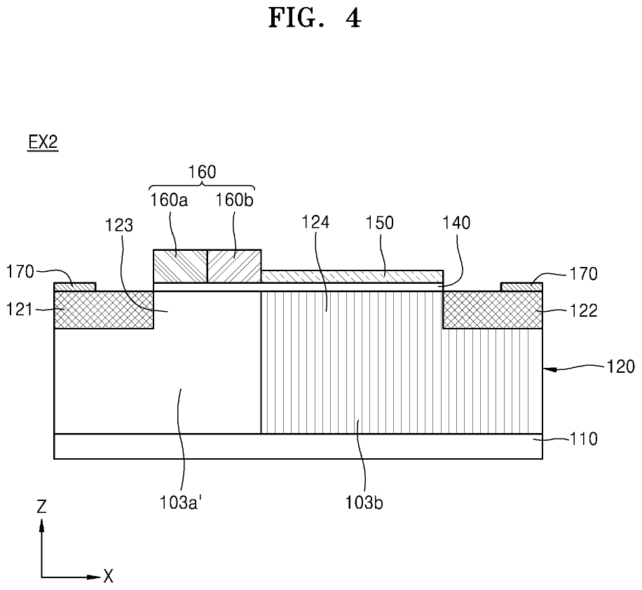

FIG. 4 is a cross-sectional view illustrating an integrated circuit device including a drain extended FinFET according to an embodiment.

The integrated circuit device EX2 is similar to the integrated circuit device EX1 of FIGS. 1 to 3B except that the channel 123 is formed to have the first conductivity type, for example, a p-type well 103a′. In the description of FIG. 4, descriptions already given with reference to FIGS. 1 to 3B are briefly given or omitted.

In an embodiment, the integrated circuit device EX2 includes a fin body 120, a source 121, a drain 122, a channel 123, a drain extension region 124, a gate insulating film 140, a high-permittivity field plate 150, a double gate 160, and a contact electrode 170. The high-permittivity field plate 150 may be a layer with high-permittivity.

The fin body 120 may have a first conductivity type, for example, a p-type well 103a′ and a second conductivity type, for example, an n-type well 103b. In the fin body 120, the source 121, the channel 123, the drain extension region 124, and the drain 122 may be sequentially disposed in the first direction (X direction). The source 121 may be formed in the p-type well 103a′, and a drain 122 may be formed in the n-type well 103b.

The gate insulating film 140 may be formed on the p-type well 103a′ and the n-type well 103b between the source 121 and drain 122. The high-permittivity field plate 150 may be formed on the n-type well 103b. The double gate 160 may be formed on the p-type well 103a′. The channel 123 may be formed in the p-type well 103a′ between the source 121 and the drain 122. The channel 123 may be formed in the p-type well 103a′ below the double gate 160. The double gate 160 may include a first gate 160a having a first work function and a second gate 160b having a second work function that is less than the first work function.

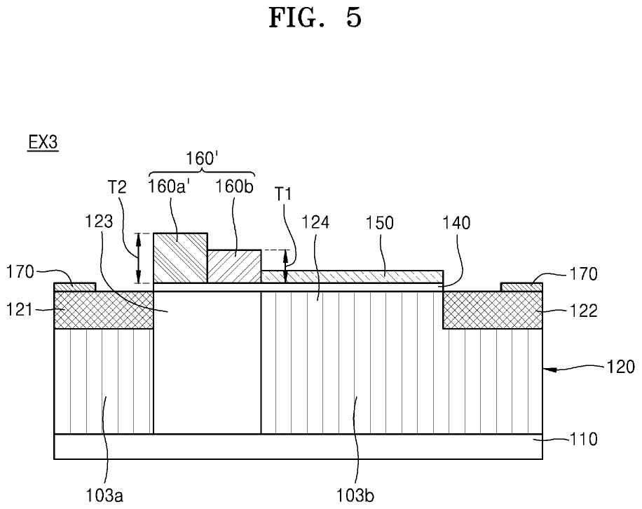

FIG. 5 is a cross-sectional view illustrating an integrated circuit device EX3 including a drain extended FinFET according to an embodiment.

The integrated circuit device EX3 is the same as the integrated circuit device EX1 of FIGS. 1 to 3B except for having differences in thicknesses T1 and T2 of the double gate 160. In the description of FIG. 5, descriptions already given with reference to FIGS. 1 to 3B are briefly given or omitted.

In an embodiment, the integrated circuit device EX3 includes a fin body 120, a source 121, a drain 122, a channel 123, a drain extension region 124, a gate insulating film 140, a high-permittivity field plate 150, a double gate 160′, and a contact electrode 170.

The fin body 120 may have a first conductivity type, for example, a p-type well 103a, a channel 123, and a second conductivity type, for example, an n-type well 103b. In the fin body 120, the source 121, the channel 123, the drain extension region 124, and the drain 122 may be sequentially disposed in the first direction (X direction). The source 121 may be formed in the p-type well 103a, and the drain 122 may be formed in the n-type well 103b.

The gate insulating film 140 may be formed on the p-type well 103a and the n-type well 103b between the source 121 and the drain 122. The channel 123 may be formed in the p-type well 103a between the source 121 and the drain 122. The channel 123 may be formed in the p-type well 103a under the double gate 160′. The high-permittivity field plate 150 may be formed on the n-type well 103b. The double gate 160′ may be formed on the channel 123.

The double gate 160′ may include a first gate 160a′ having a first work function and a second gate 160b having a second work function that is less than the first work function. The first gate 160a′ may have a second thickness T2. In an embodiment, the second gate 160b has a first thickness T1 that is less than the second thickness T2 of the first gate 160a′.

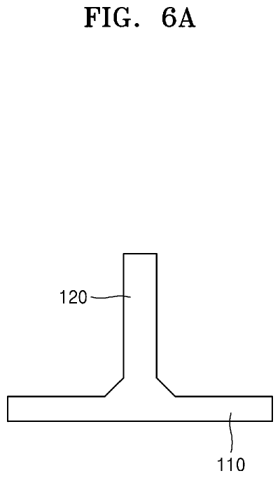

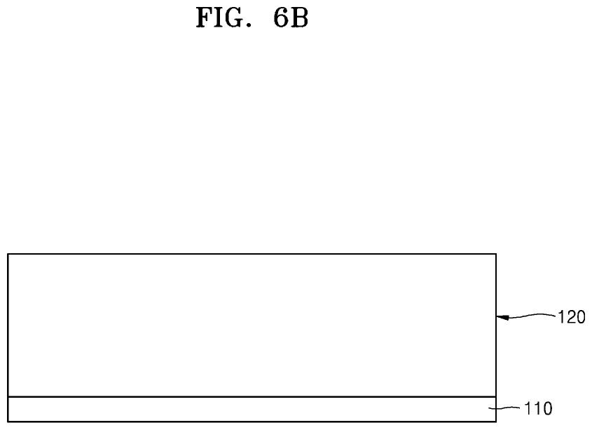

FIGS. 6A to 13B are cross-sectional views illustrating a method of manufacturing an integrated circuit device including a drain extended FinFET according to an embodiment.

Specifically, FIGS. 6A, 7A, 8A, 9A, 10A, 11A, 12A, and 13A and FIGS. 6B, 7B, 8B, 9B, 10B, 11B, 12B, and 3B are cross-sectional views taken along lines A-A′ and B-B′ of the integrated circuit element EX1 of FIG. 2, respectively. FIGS. 6A, 7A, 8A, 9A, 10A, 11A, 12A, and 13A and FIGS. 6B, 7B, 8B, 9B, 10B, 11B, 12B, and 3B are cross-sectional views illustrating a method of manufacturing the integrated circuit device EX1 of FIGS. 3A and 3B, respectively. In the descriptions of FIGS. 6A to 13B, descriptions already given with reference to FIGS. 1 to 3B are briefly given or omitted.

The method of manufacturing the integrated circuit device EX1 of FIGS. 6A to 13B, according to an embodiment of the inventive concept, includes forming a fin body 120 on a substrate 110, forming a lower insulating layer 130 on the substrate 110 to expose the fin body 120, and forming a drain extension region 124 in the fin body 120.

In addition, the method of manufacturing an integrated circuit device of FIGS. 6A to 13B, according to an embodiment of the inventive concept, includes forming a gate insulating film 140 to surround the fin body 120, forming a high-permittivity field plate 150 to surround a partial region of the gate insulating film 140, forming a source 121 and a drain 122 in the fin body 120, and forming a double gate 160 on the gate insulating film 150 over the drain extension region 124.

Referring to FIGS. 6A and 6B, the fin body 120 is formed on the substrate 110. The substrate 110 may be a semiconductor such as silicon (Si) or silicon on insulator (SOI). The fin body 120 may be formed by patterning and etching the substrate 110 using a photolithography process so as to protrude upward from the substrate 110. In an embodiment, portions of the substrate 110 are removed to form a protrusion that corresponds to the fin body 120.

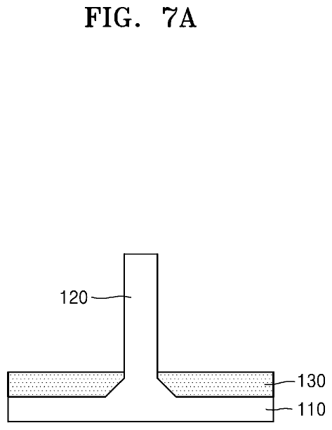

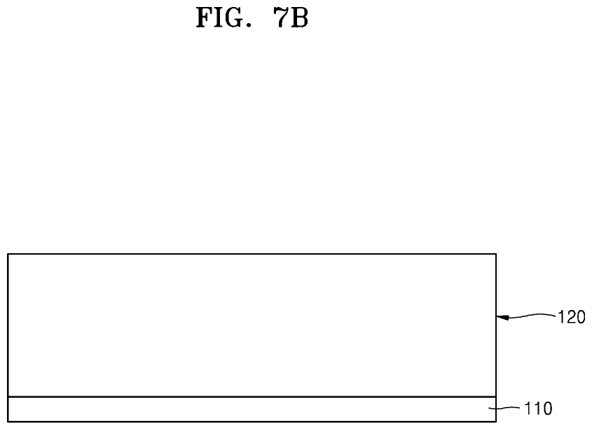

Referring to FIGS. 7A and 7B, the lower insulating layer 130 is formed on both sides of the fin body 120. The lower insulating layer 130 may be formed on the substrate 110 on both sides of the fin body 120, and an upper surface of the fin body 120 may be higher than an upper surface of the lower insulating layer 130. In an embodiment, the fin body 120 has two sloped sides and the lower insulating layer 130 is formed on both of the sloped sides.

The fin body 120 may have a form protruding from the lower insulating layer 130. For example, after forming an insulating material layer on the fin body 120 and the substrate 110, the fin body 120 may be exposed by using a chemical mechanical planarization or polishing (CMP) and etching process. A material of the lower insulating layer 130 may include any one of silicon oxide (SiO₂) and silicon nitride (Si₃N₄).

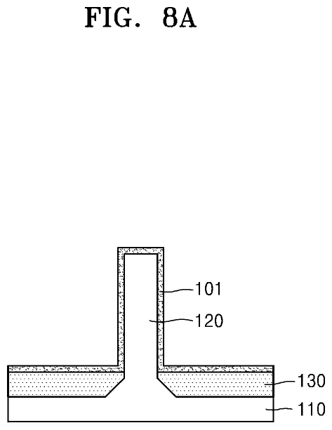

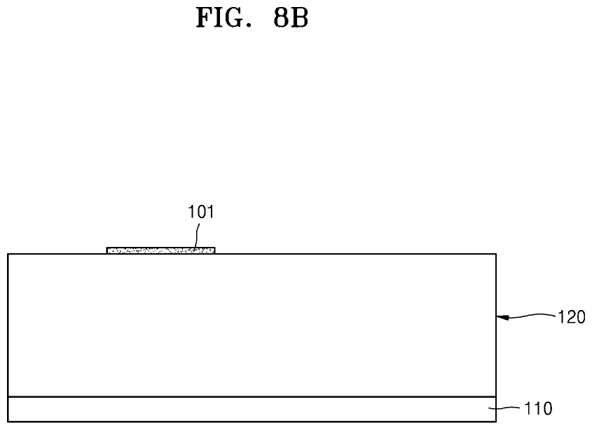

Referring to FIGS. 8A and 8B, a first dummy gate 101 may be formed on the fin body 120 and the lower insulating layer 130. The first dummy gate 101 may be formed by using a patterning process using a lithography process and an etching process. The first dummy gate 101 may include polysilicon (Poly Si) or a photoresist.

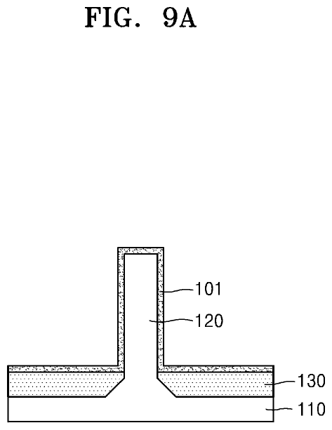

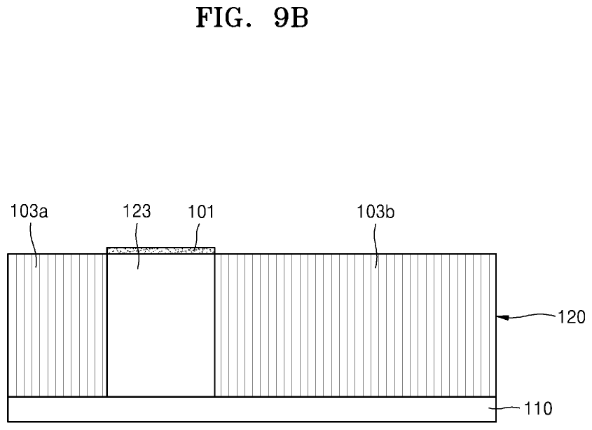

Referring to FIGS. 9A and 9B, the channel 123 and the drain extension region 124 may be formed in the fin body 120. For example, the p-type well 103a and the n-type well 103b may be formed by injecting a p-type or n-type dopant into the fin body 120 using the first dummy gate 101 as a mask.

Accordingly, the fin body 120 corresponding to a lower portion of the first dummy gate 101 into which the dopant 103 is not injected may function as the channel 123, and the drain extension region 124 may be formed in the fin body 120 excluding the channel 123. A region of the fin body 120 excluding regions in which the source 121 and the drain 122 are formed, as described below, may function as the drain extension region 124.

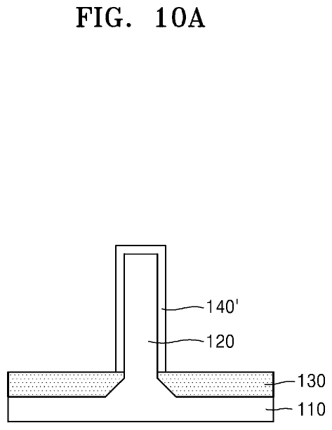

Referring to FIGS. 10A and 10B, after removing the first dummy gate 101, a gate insulating material film 140′ is formed on the fin body 120 and a high-permittivity field plate material film 150′ is formed on the gate insulating material film 140′ over the fin body 120. The gate insulating material film 140′ may be formed to surround both upper and side surfaces of the fin body 120. The high-permittivity field plate material film 150′ may be formed to surround all of a partial region of the gate insulating material film 140′ surrounding the fin body 120. The high-permittivity field plate material film 150′ may be formed on a portion of the gate insulating material film 140′.

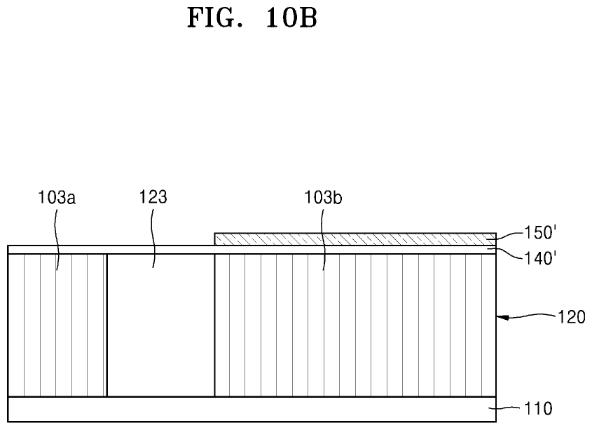

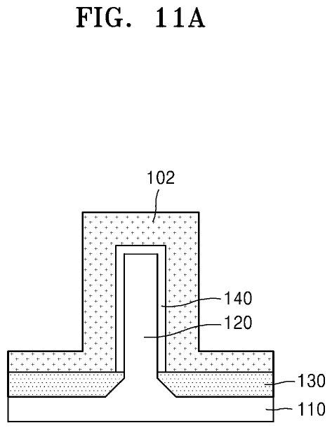

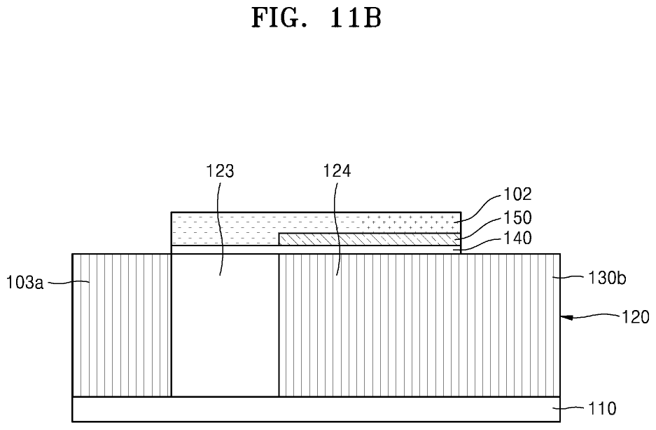

Referring to FIGS. 11A and 11B, a second dummy gate 102 may be formed on the gate insulating material film 140′ (refer to FIGS. 10A and 10B) and the high-permittivity field plate material film 150′ (refer to FIGS. 10A and 10B). The second dummy gate 102 may be formed by using a patterning process using a lithography process and an etching process. The gate insulating material film 140′ (refer to FIGS. 10A and 10B) and the high-permittivity field plate material film 150′ (refer to FIGS. 10A and 10B) are etched using the second dummy gate 102 as a mask to expose the upper portion of the fin body 120 where the source 121 and drain 122 are formed.

Accordingly, the gate insulating film 140 and the high-permittivity field plate 150 are formed on the fin body 120. The gate insulating film 140 may be formed to surround both the upper and side surfaces of the fin body 120, and the high-permittivity field plate 150 may be formed to surround a portion of the gate insulating film 140 that surrounds the fin body 120.

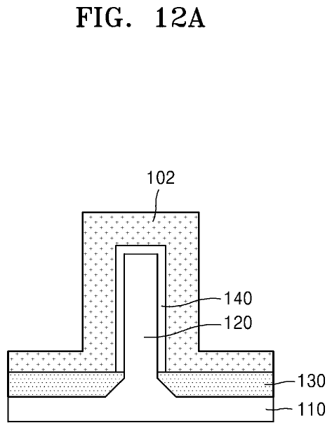

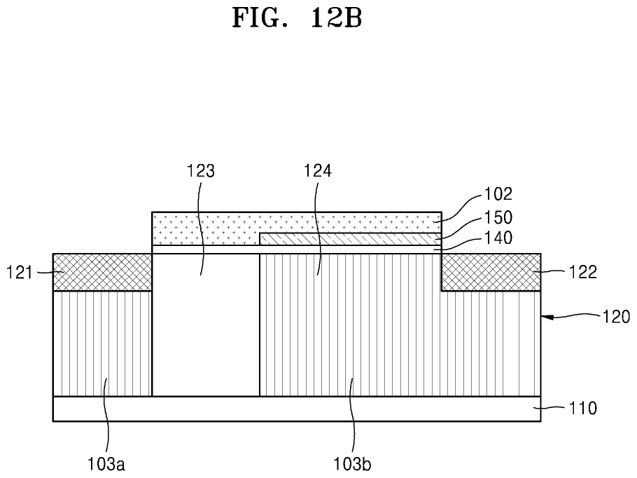

Referring to FIGS. 12A and 12B, the source 121 and the drain 122 are formed in the fin body 120. The source 121 and the drain 122 may be formed by implanting a high-concentration n-type dopant into the fin body 120 exposed through the second dummy gate 102. For example, the high-concentration n-type dopant may be implanted in an upper surface of the fin body 120. That is, the source 121 and the drain 122 may be formed in the p-type well 103a and the n-type well 103b, respectively. In the n-type well 103b, a region excluding the region where the drain 122 is formed may become the drain extension region 124.

In some embodiments, after etching a portion of the fin body 120 where the source 121 and the drain 122 are formed using the second dummy gate 102, the source 121 and the drain 122 including the n-type dopant may be formed using a selective epitaxial growth method. As shown in FIG. 12B, the fin body 120 may have a structure in which the source 121, the channel 123, the drain extension region 124, and the drain 122 are sequentially formed.

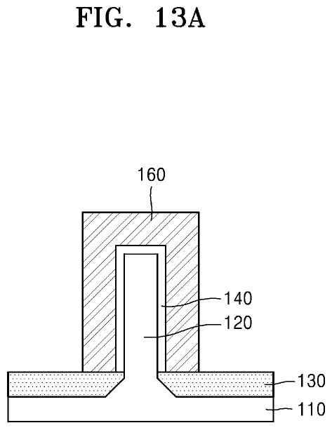

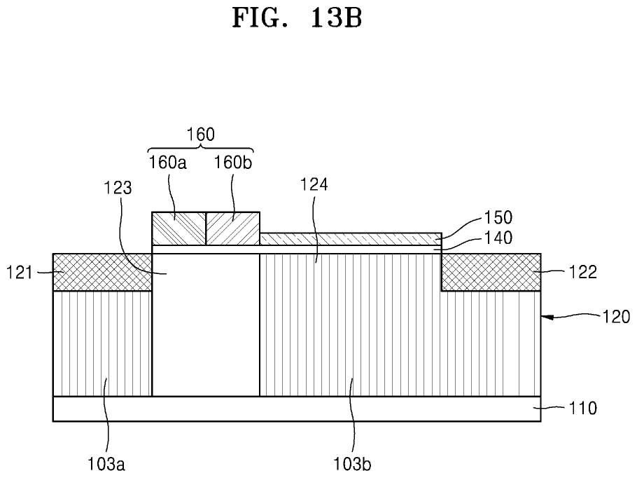

Referring to FIGS. 13A and 13B, after removing the second dummy gate 102, the double gate 160 may be formed on the gate insulating film 140. The double gate 160 may be formed at a position corresponding to the channel 123 or in a region partially including the channel 123 and the drain extension region 124.

Subsequently, as shown in FIG. 3B, the contact electrode 170 may be formed on the source 121 and the drain 122, respectively. The contact electrode 170 may be formed on the fin body 120 corresponding to the source 121 and the drain 122. In some embodiments, the contact electrode 170 may be formed such that, after forming a separate insulating layer on the outside of the drain extended FinFET, via holes are formed in the insulating layer, and then the contact electrodes 170 are connected to the source 121 and the drain 122 through the via holes.

Hereinafter, electrical characteristics of the integrated circuit devices EX1 to EX3 including the high-permittivity field plate 150 and the double gate 160 described above will be described. In the following drawings, for convenience of description, electrical characteristics of an integrated circuit device DMGFP-FF having a high-permittivity field plate 150 and a double gate 160 according to an embodiment of the inventive concept and an integrated circuit device SMG-FF according to a comparative example are compared.

The integrated circuit device SMG-FF according to the comparative example includes the high-permittivity field plate 150 and a single gate instead of a double gate in the integrated circuit devices EX1 to EX3 described above. In the following drawings, like reference numerals as in FIGS. 1 to 13B indicate like members.

Example parameters of the integrated circuit device DMGFP-FF according to the inventive concept described below are as follows, but the present inventive concept is not limited thereto.

For example, a height H of the fin body 120 may be 54 nm, a width W of the fin body 120 may be 7 nm, and a channel length L3 may be 80 nm. A length L2 of the drain extension region 124 may be 80 nm, and the doping concentration of the first conductivity type impurity of the channel 123 may be 1×10¹⁸ cm⁻³. The doping concentration of the second conductivity type impurity of the drain extension region 124 may be 2×10¹⁸ cm⁻³, and the doping concentration of the first conductivity type impurity of the substrate 110 may be 1×10¹⁵ cm⁻³.

Lengths of the first gate 160a and the second gate 160b may be 40 nm, the work function of the first gate 160a may be 4.6 eV, and the work function of the second gate 160b may be 4.1 eV. In an embodiment, the high-permittivity field plate 150 includes or is hafnium oxide (HfO₂). In an embodiment, the high-permittivity field plate 150 has a permittivity k of 25, and may have a thickness of 10 nm.

FIG. 14 is a diagram illustrating an electric field distribution of an integrated circuit device having a high-permittivity field plate and a double gate according to an embodiment.

FIG. 14 is a graph illustrating electric fields in a transverse direction (X direction) of an integrated circuit device DMGFP-FF according to an embodiment and an integrated circuit device SMG-FF according to a comparative example in a gate-off state in which a gate-source voltage V_{GS} of 0.0 V and a drain-source voltage V_{DS} of 3.3 V are applied.

In FIG. 14, the section having X-axis positions of −40 nm to 0 nm is a source and the section having X-axis positions of 160 nm to 200 nm is a drain. In FIG. 14, the Y-axis represents an electric field. In FIG. 14, a high work function gate region HWF, a low work function gate region LWF, and a drain extension region DE are indicated.

As shown in FIG. 14, the integrated circuit device SMG-FF according to the comparative example has a high electric field peak between the low work function gate region LWF and the drain extension region DE, that is, between the channel and the drain extension region DE.

In contrast, the integrated circuit device DMGFP-FF according to an embodiment has an electric field peak between the low work function gate region LWF and the drain extension region DE, that is, between the channel and the drain extension region DE, which is a more reduced electric field peak than in the integrated circuit device SMG-FF of the comparative example. In the integrated circuit device DMGFP-FF according to an embodiment, the electric field is uniformly distributed (or dispersed) throughout the drain extension region DE. Accordingly, the integrated circuit device DMGFP-FF according to an embodiment may obtain a high breakdown voltage by reducing impact ionization.

In addition, the integrated circuit device DMGFP-FF according to an embodiment may have a stepped electric field in the high work function gate region HWF and the low work function gate region LWF. The integrated circuit device DMGFP-FF according to an embodiment may have a high electric field peak between the high work function gate region HWF and the low work function gate region LWF. Accordingly, as described below, the integrated circuit device DMGFP-FF according to an embodiment may increase the conductivity of a semiconductor layer constituting a channel or drain extension region, and accordingly, a driving resistance may be reduced and transconductance may be increased.

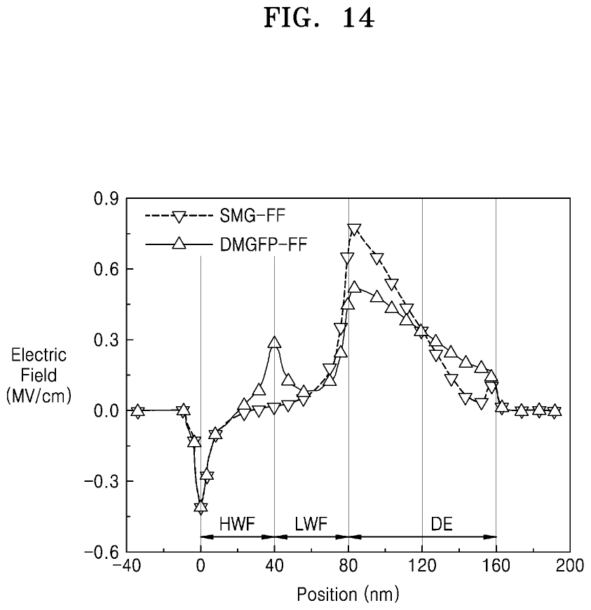

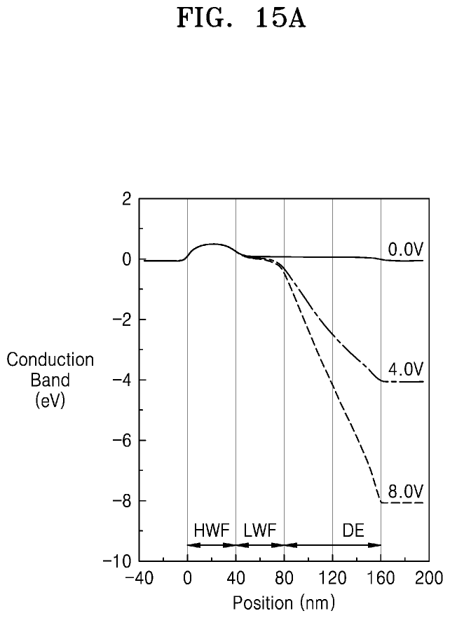

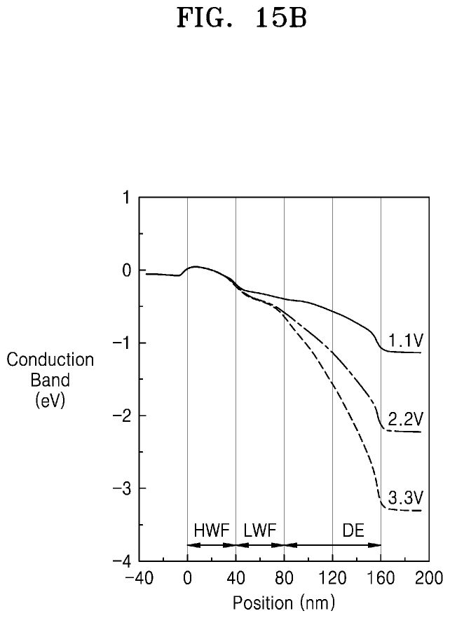

FIGS. 15A and 15B are diagrams illustrating a conduction band of an integrated circuit device having a high-permittivity field plate and a double gate according to an embodiment. Specifically, FIGS. 15A and 15B show a conduction band in a transverse direction

(X direction) according to a drain-source voltage V_{DS} of an integrated circuit device DMGFP-FF in a gate-off state to which a gate-source voltage V_{GS} of 0.0 V is applied and a gate-on state to which a gate-source voltage V_{GS} of 0.7 V is applied, respectively. FIG. 15A shows drain-source voltages V_{DS} of 0.0 V, 4.0 V, and 8.0 V, and FIG. 15B shows drain-source voltages V_{DS} of 1.1 V, 2.20 V, and 3.3 V.

As shown in FIGS. 15A and 15B, in the integrated circuit device DMGFP-FF according to an embodiment, the conduction band of the high work function gate region HWF does not change but is fixed when a drain-source voltage V_{DS} is in both a gate-off state and a gate-on state.

Therefore, in the integrated circuit device DMGFP-FF according to an embodiment, a drain induced barrier lowering (DIBL) effect and a channel length modulation (CLM) effects may be suppressed by the drain-source voltage VDs, thereby increasing breakdown voltage and output resistance.

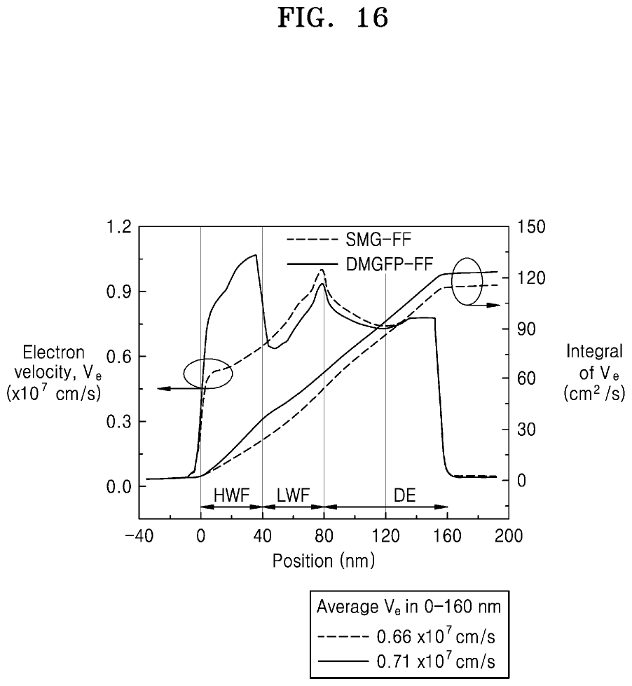

FIG. 16 is a diagram illustrating an electron velocity and an integral of electron velocity of an integrated circuit device having a high-permittivity field plate and a double gate according to an embodiment.

FIG. 16 is a graph showing an electron velocity Ve and an integral of the electron velocity Ve of an integrated circuit device DMGFP-FF according to an embodiment and an integrated circuit device SMG-FF according to a comparative example in a driving state in which a gate-source voltage V_{GS} of 0.7 V and a drain-source voltage V_{DS} of 3.3 V are applied.

In the integrated circuit device DMGFP-FF according to an embodiment, an electric field peak formed in a region where a first gate and a second gate, which have different work functions, contact each other may accelerate electrons. Therefore, as shown in FIG. 16, the integrated circuit device DMGFP-FF according to an embodiment has an electron velocity Ve that is faster than that of the integrated circuit device SMG-FF according to the comparative example, and the integral value of the electron velocity is also greater.

As shown in FIG. 16, the integrated circuit device DMGFP-FF according to an embodiment has a higher average electron velocity in the high work function gate region HWF, the low work function gate region LWF, and the drain extension region DE than the integrated circuit device SMG-FF according to the comparative example, and accordingly, the integral value of the electron velocity may be greater.

Through this, the integrated circuit device DMGFP-FF according to an embodiment may increase the conductivity of the semiconductor layer constituting the channel or drain extension region, thereby reducing driving resistance and increasing transconductance.

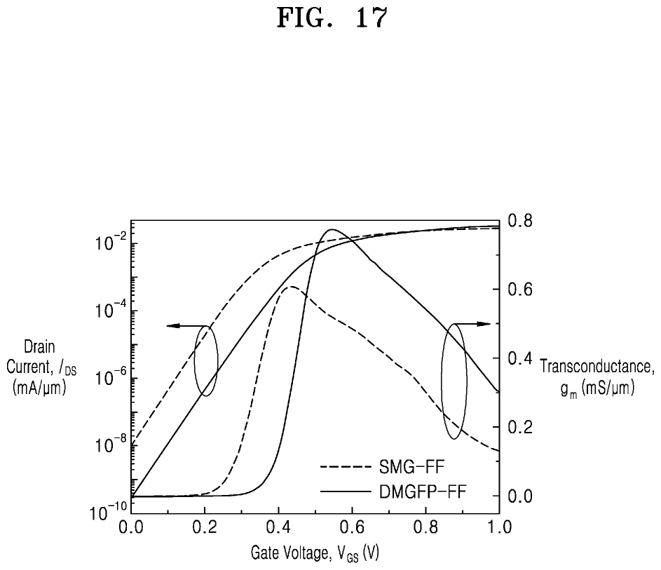

FIG. 17 is a diagram illustrating a drain current and transconductance according to a gate voltage of an integrated circuit device having a high-permittivity field plate and a double gate according to an embodiment of the inventive concept.

In FIG. 17, the X-axis indicates a gate voltage (gate-source voltage Vas), the left Y-axis indicates a drain current I_{DS}, and the right Y-axis indicates a transconductance gₘ.

As shown in FIG. 17, it may be seen that the integrated circuit device DMGFP-FF according to an embodiment has a lower leakage current and a higher drain current (i.e., driving current) than the integrated circuit device SMG-FF according to the comparative example.

In addition, it may be seen that the integrated circuit device DMGFP-FF according to an embodiment has a higher transconductance peak value than the integrated circuit device SMG-FF according to the comparative example.

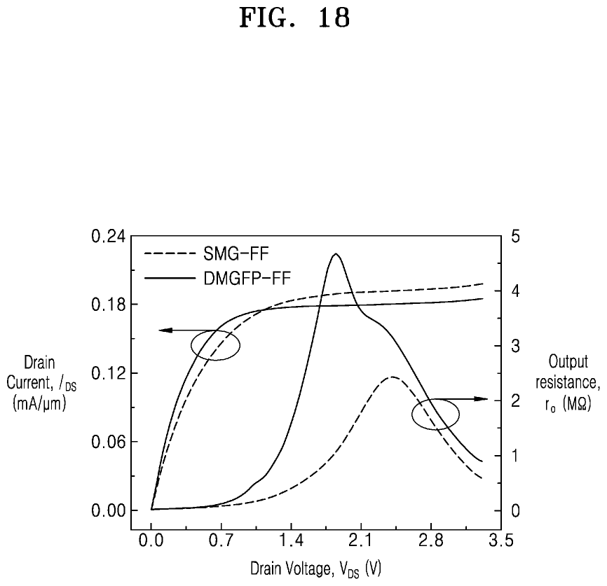

FIG. 18 is a diagram illustrating a drain current and output resistance according to a drain voltage of an integrated circuit device having a high-permittivity field plate and a double gate according to an embodiment.

In FIG. 18, the X axis indicates a drain voltage (drain-source voltage V_{DS}), the left Y axis indicates a drain current I_{DS}, and the right Y axis indicates an output resistance ro.

As shown in FIG. 18, the integrated circuit device DMGFP-FF according to an embodiment may have a lower drive resistance and a higher output resistance peak value than the integrated circuit device SMG-FF according to the comparative example. As shown in FIG. 18, the integrated circuit device DMGFP-FF according to an embodiment may have a higher drain current saturation value than the integrated circuit device SMG-FF according to the comparative example.

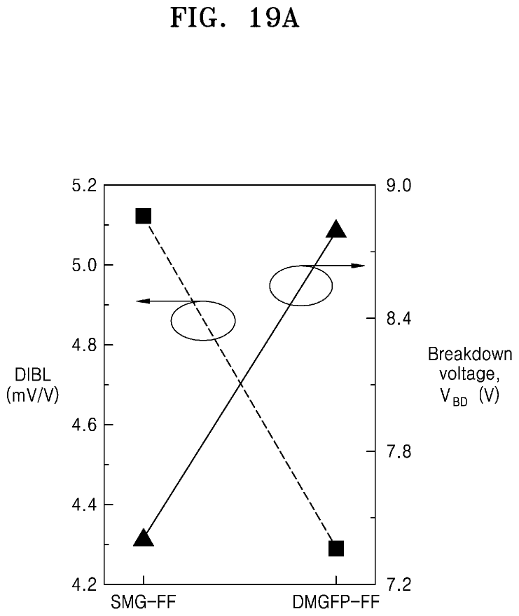

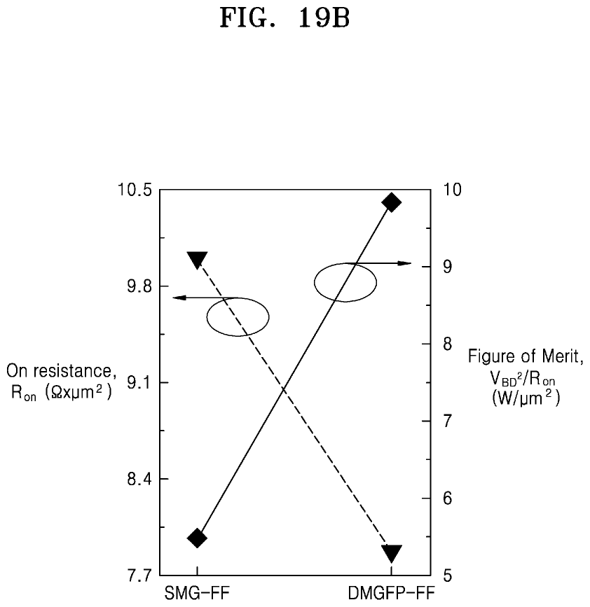

FIGS. 19A and 19B are diagrams illustrating a DIBL value, a breakdown voltage, a driving resistance, and a figure of merit of an integrated circuit device having a high-permittivity field plate and a double gate according to an embodiment.

In FIG. 19A, the left Y-axis represents a drain induced barrier lowering DIBL value and the right Y-axis represents a breakdown voltage VBD. In FIG. 19B, the left Y-axis represents driving resistance (On resistance, Ron) and the right Y-axis represents figure of merit V_{BD}²/Rₒₙ.

As shown in FIG. 19A, it may be seen that the integrated circuit device DMGFP-FF according to an embodiment has a lower DIBL value and a higher breakdown voltage VBD than the integrated circuit device SMG-FF according to the comparative example.

As shown in FIG. 19B, the integrated circuit device DMGFP-FF according to an embodiment has a lower drive resistance Rₒₙ than the integrated circuit device SMG-FF according to the comparative example, and accordingly, the figure of merit V_{BD}²/Rₒₙ is high.

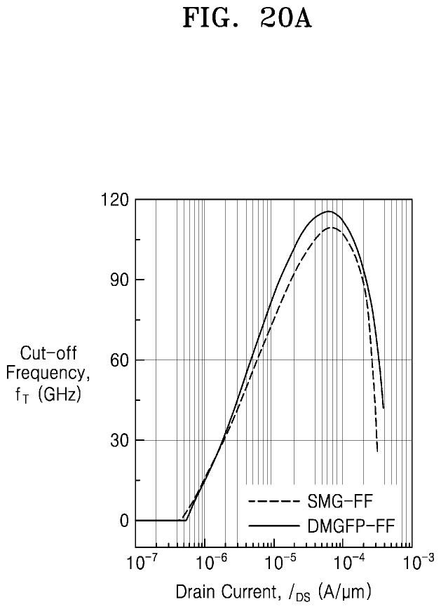

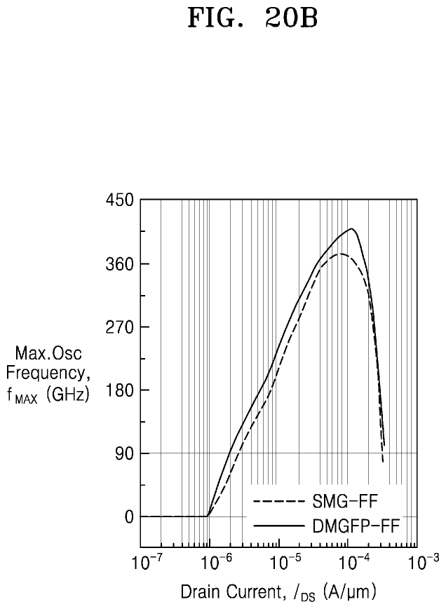

FIGS. 20A and 20B are diagrams illustrating a cut-off number and a maximum oscillation frequency according to a drain current of an integrated circuit device having a high-permittivity field plate and a double gate according to an embodiment.

FIG. 20A shows a cut-off frequency f_{T} according to a drain current (drain-source current, I_{DS}), and FIG. 20B shows a maximum oscillation frequency (Maximum (Max.) Oscillation (Osc.) Frequency, f_{MAX}) according to a drain current (drain-source current, I_{DS}). As shown in FIG. 20A, due to the effect of increased transconductance due to the double gate and high permittivity field plate, the integrated circuit device DMGFP-FF according to an embodiment shows a higher cut-off frequency f_{T} compared to the integrated circuit device SMG-FF according to the comparative example. As shown in FIG. 20B, due to the effect of increased transconductance due to the double gate and high permittivity field plate, the integrated circuit device DMGFP-FF according to an embodiment shows a higher maximum vibration frequency f_{MAX} compared to the integrated circuit device SMG-FF according to the comparative example.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a fin body;
a source and a drain disposed on the fin body;
a channel disposed in the fin body between the source and the drain;
a drain extension region disposed in the fin body between the drain and the channel;
a gate insulating film disposed on the channel and the drain extension region;
a high-permittivity layer disposed on the gate insulating film over the drain extension region; and
a double gate including a first gate disposed on the gate insulating film above the channel adjacent to the source and a second gate in contact with the first gate,
wherein a first work function of the first gate is greater than a second work function of the second gate.

2. The integrated circuit device of claim 1, wherein the gate insulating film surrounds both upper and side surfaces of the fin body, and
the double gate surrounds both upper and side surfaces of the gate insulating film on an upper portion of the fin body.

3. The integrated circuit device of claim 1, wherein
the high-permittivity layer includes a material having a higher permittivity than silicon dioxide (SiO₂).

4. The integrated circuit device of claim 1, wherein the first gate and the second gate include different materials.

5. The integrated circuit device of claim 1, wherein the first gate has a thickness greater than that of the second gate.

6. The integrated circuit device of claim 1, wherein the first gate and the second gate include a same material having different impurity doping concentrations.

7. The integrated circuit device of claim 1, wherein the source is disposed on a first conductivity type well having a first conductivity type, and
the drain and the drain extension region are disposed on a second conductivity type well having a second conductivity type opposite to the first conductivity type.

8. The integrated circuit device of claim 1, wherein the source and the channel are disposed on a first conductivity type well, and
the drain and the drain extension region are disposed on a second conductivity type well having a second conductivity type opposite to the first conductivity type.

9. An integrated circuit device comprising:
a substrate;
a fin body protruding above the substrate;
a source and a drain disposed on the fin body;
a channel disposed in the fin body between the source and the drain;
a drain extension region disposed in the fin body between the drain and the channel;
a gate insulating film disposed on the channel and the drain extension region;
a high-permittivity layer disposed on the gate insulating film over the drain extension region; and
a double gate including a first gate disposed on the gate insulating film above the channel adjacent to the source and a second gate in contact with the first gate,
wherein the gate insulating film surrounds both upper and side surfaces of the channel and the drain extension region, and
wherein the double gate surrounds both upper and side surfaces of the gate insulating film.

10. The integrated circuit device of claim 9, further comprising a lower insulating layer covering a lower side surface of the fin body.

11. The integrated circuit device of claim 9, wherein the substrate includes a first semiconductor layer, the channel includes a second semiconductor layer having a same conductivity type as the first semiconductor layer.

12. The integrated circuit device of claim 9, wherein the high-permittivity layer includes a material having a higher dielectric constant than silicon dioxide (SiO₂), and the first gate has a thickness greater than that of the second gate.

13. The integrated circuit device of claim 9, wherein the first gate and the second gate include different materials or a same material having different impurity doping concentrations.

14. The integrated circuit device of claim 9, wherein the source is disposed on a first conductivity type well having a first conductivity type, and
the drain and the drain extension region are disposed on a second conductivity type well having a second conductivity type opposite to the first conductivity type.

15. The integrated circuit device of claim 9, wherein the source and the channel are disposed on a first conductivity type well having a first conductivity type, and
the drain and the drain extension region are disposed on a second conductivity type well having a second conductivity type opposite to the first conductivity type.

16. An integrated circuit device comprising:
a substrate;
a fin body protruding in a vertical direction perpendicular to a surface of the substrate and extending in a horizontal direction parallel to a surface of the substrate;
a lower insulating layer covering a lower side surface of the fin body;
a source and a drain spaced apart from each other in the horizontal direction on respective sides of the fin body;
a channel disposed in the fin body between the source and the drain in the horizontal direction;
a drain extension region disposed in the fin body between the drain and the channel in the horizontal direction;
a gate insulating film disposed on the channel and the drain extension region;
a high-permittivity layer disposed on the gate insulating film above the drain extension region;
a first gate disposed on the gate insulating film above the channel and adjacent to the source and having a first work function; and
a second gate disposed on the gate insulating film in contact with the first gate and having a second work function that is less than the first work function.

17. The integrated circuit device of claim 16, wherein the substrate includes a first semiconductor layer, and the channel includes a second semiconductor layer of a same conductivity type as that of the first semiconductor layer.

18. The integrated circuit device of claim 16, wherein the source is disposed on a first conductivity type well having a first conductivity type, and
the drain and the drain extension region are disposed on a second conductivity type well having a second conductivity type opposite to the first conductivity type.

19. The integrated circuit device of claim 16, wherein the source and the channel are disposed on a first conductivity type well having a first conductivity type, and
the drain and the drain extension region are disposed on a second conductivity type well having a second conductivity type opposite to the first conductivity type.

20. The integrated circuit device of claim 16, wherein the high-permittivity layer includes a material having a higher dielectric constant than silicon dioxide (SiO₂), and
the first gate and the second gate include different materials from each other.
